(19) United States
(12) Patent Application Publication
(10) Pub. No.: US 2014/0368169 A1
(43) Pub. Date: Dec. 18, 2014

(54) Battery having a Control Device and an Additional Interface

(71) Applicants: ROBERT BOSCH GMBH, Stuttgart (DE); SAMSUNG SDI CO., LTD., Yongin-si, Gyeonggi-do (JP)

(72) Inventor: Ulrich Zimmermann, Hessigheim (DE)

(73) Assignees: Robert Bosch GmbH, Stuttgart (DE); Samsung SDI Co., Ltd., Yongin-si, Gyeonggi-do (JP)

(21) Appl. No.: 14/352,128

(22) PCT Filed: Sep. 12, 2012
(86) PCT No.: PCT/EP2012/067751

§ 371 Date: Aug. 6, 2014

(30) Foreign Application Priority Data
Oct. 18, 2011 (DE) 10 2011 084 689.1

(51) Int. Cl. H02J 7/00; G01R 31/28; G01R 31/36

(52) U.S. Cl. CPC H02J 7/0029; H02J 7/007; G01R 31/3606; G01R 31/2829
USPC 320/135

(57) ABSTRACT

A battery includes a control device having an interface configured to enable a measurement of battery properties and/or of a discharge of the battery, in the event that the control device has failed. A motor vehicle, such as an electrical motor vehicle, includes the battery. An analysis plug is configured to replace a maintenance plug of the battery. A method for monitoring the battery includes measuring battery properties and/or a discharge of the battery via an interface, in the event that the control device has failed.

The present invention relates to a battery having a controller and an additional interface, to a motor vehicle having a battery according to the invention, to an analysis connector for a battery according to the invention and to a method for monitoring a battery.

### PRIOR ART

It is becoming apparent that in future there will be increased use of new battery systems both for static applications (e.g. in the case of wind power installations) and in vehicles such as hybrid and electric vehicles, said battery systems being subject to very great demands in terms of reliability. The background to these great demands is that failure of the battery can lead to failure of the overall system or even to a safety-related problem. In wind power installations, for example, batteries are used to protect the installation against inadmissible operating states in a high wind by virtue of rotor blade adjustment.

In order to ensure this protection, batteries usually comprise a controller that is able to monitor operating data for the battery and to reliably control the operation of the battery. The controller can be used to communicate via a data line in order to request relevant state data for the battery. In addition, this controller can be used to connect the internal high voltage of the battery to the outer connections in order to draw energy from the battery.

By way of example, laid-open specification DE 10 2009 046 564 A1 discloses a battery controller architecture according to which a controller comprises a microcontroller and a nanocontroller that are connected to monitoring units on the individual battery cells by means of a communication bus and are thereby able to detect and monitor various properties of the battery or of individual battery cells, for example temperature and state of charge.

A disadvantage of the prior art is that communication is possible exclusively via the integrated controller and there is no longer access to the battery in the event of failure of the often extremely complex controller, which means that it becomes impossible to read operating data for the battery and/or to discharge the battery in the event of a critical state occurring. This frequently results in damaged batteries needing to be disposed of with a high level of involvement and cost.

### DISCLOSURE OF THE INVENTION

The invention provides a battery having a controller, which battery comprises an interface that is designed to allow measurement of battery properties and/or discharge of the battery when the controller has failed. As a result of the battery comprising an additional interface, redundant access to elementary data and functions of the battery is made possible. The interface can be used for measurement access to the inside of the battery, even when the controller of the battery has failed. This allows insights about the state of the battery to be obtained, which can be used to plan suitable further handling of the battery, for example opening and/or repair.

The battery may preferably be a lithium ion battery. Preferably, the interface is designed to allow measurement of at least one temperature inside the battery when the controller has failed. By way of example, relevant temperature sensors can be tapped that would indicate critical temperatures inside the battery.

Preferably, the interface is designed to allow measurement of a battery voltage when the controller has failed. In one preferred embodiment, the battery also comprises a multiplicity of battery cells and/or a multiplicity of battery modules. Preferably, the interface is designed to allow measurement of the voltage of at least one battery cell and/or of at least one battery module when the controller has failed. By way of example, the pack voltage or particular elemental voltages can be tapped off. From this it is possible to identify the state of charge or increased self-discharge of the battery. Furthermore, it is therefore possible to use this line to slowly discharge the battery and hence to minimize its hazard potential.

Preferably, the battery also comprises at least one measurement circuit for at least one battery cell and/or at least one battery module and also a communication bus for communication between the controller and the at least one measurement circuit, wherein the interface is designed to allow access to the communication bus when the controller has failed. Preferably, the interface is designed to allow discharge of the battery when the controller has failed.

In a further preferred embodiment, the battery comprises a maintenance connector. The interface can advantageously be arranged in the region of the maintenance connector, since the latter is generally positioned at easily accessible locations in the vehicle in order to allow interruption of the circuit between the individual modules of the battery.

Preferably, the maintenance connector can be replaced by an analysis connector. Such an analysis connector could be interchanged with the normal connector in the workshop, for example, and could then allow the access described above.

The maintenance connector and/or the analysis connector may comprise a voltage indicator that is designed to indicate whether the state of charge of the battery is critical when the controller has failed. In addition, the maintenance connector and/or the analysis connector may comprise a warning indicator that is designed to indicate whether the temperature of the battery has increased when the controller has failed. For this purpose, the connector could be connected to temperature sensors inside the battery. The maintenance connector and/or the analysis connector may also comprise a discharge resistor. The discharge resistor could be activated using suitable resources when needed and therefore allows a damaged battery to be discharged in situ.

The advantage of such monitoring that is simple but difficult to destroy is that it is still possible to obtain some basic information about the battery state even when the battery has damage that results in failure of the battery controller and hence normal communication with the battery.

Furthermore, the invention provides a motor vehicle, particularly an electric motor vehicle, that comprises a battery according to the invention. The invention also provides an analysis connector that is designed to replace the maintenance connector of a battery according to the invention. Furthermore, a method for monitoring a battery is provided, in which an interface is used to allow measurement of battery properties and/or discharge of the battery when the controller has failed.

### DRAWINGS

An exemplary embodiment of the invention is explained in more detail with the aid of the drawing and the description below. In the drawing:

FIG. 1 shows a battery according to the invention with a maintenance connector.

### EMBODIMENTS OF THE INVENTION

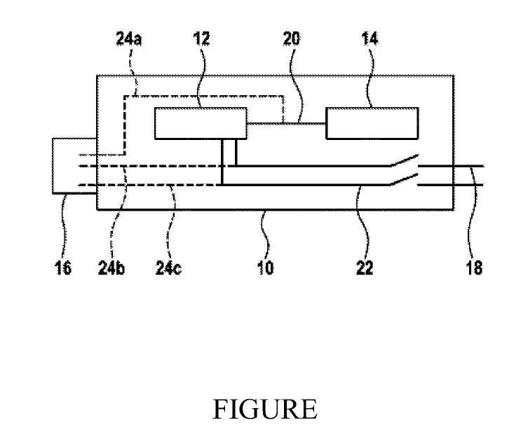

FIG. 1 shows a battery 10 that comprises a cell monitoring circuit (cell supervision circuit) 12, a battery management system 14, a maintenance connector 16 and a high-voltage connection 18. In the fully operational state of the battery 10, the battery management system 14 uses a communication bus 20 to communicate with the cell monitoring circuit 12, which is conductively connected to the high-voltage connection 18 via lines 22. Lines 24a, 24b, 24c are routed from the maintenance connector 16 to the communication bus 20 and also to the lines 22. Hence, the maintenance connector 16 is used as an interface, via which there is redundant access to elementary data and functions of the battery 10. Should the integrated battery management system 14 fail, the maintenance connector 16 can be used to continue to access the communication bus 20 by means of the line 24a, said communication bus being able to be used to read data from the cell monitoring circuit 12. In addition, if the battery management system 14 and/or the cell monitoring circuit 12 fail(s), the lines 24b, 24c can be used to continue to tap off the pack voltage and/or elemental voltages, for example the voltages of individual battery modules or individual battery cells. If a critical state occurs, the battery 10 can furthermore still be discharged safely, and without involved dismantlement, via the lines 24b, 24c, even if the battery management system 14 and/or the cell monitoring circuit 12 fail(s).

1. A battery comprising:
a controller; and
an interface configured to allow measurement of battery properties and/or discharge of the battery when the controller has failed.

2. The battery as claimed in claim 1, wherein the interface is further configured to allow measurement of at least one temperature inside the battery when the controller has failed.

3. The battery as claimed in claim 1, wherein the interface is configured to allow measurement of a battery voltage when the controller has failed.

4. The battery as claimed in claim 1, further comprising:
a multiplicity of battery cells and/or a multiplicity of battery modules.

5. The battery as claimed in claim 4, wherein the interface is further configured to allow measurement of the voltage of at least one battery cell of the multiplicity of battery cells and/or of at least one battery module of the multiplicity of battery modules when the controller has failed.

6. The battery as claimed in claim 4, further comprising:
at least one measurement circuit for at least one battery cell and/or at least one battery module; and
a communication bus for communication between the controller and the at least one measurement circuit,
wherein the interface is configured to allow access to the communication bus when the controller has failed.

7. The battery as claimed in claim 1, further comprising:
a maintenance connector,
wherein the interface is located in a region of the maintenance connector, and
wherein the maintenance connector is configured to be replaced by an analysis connector.

8. The battery as claimed in claim 7, wherein at least one of the maintenance connector and the analysis connector comprises an indicator that is configured to indicate whether a state of charge of the battery is critical and/or whether a temperature of the battery is increased, when the controller has failed.

9. The battery as claimed in claim 7, wherein at least one of the maintenance connector and the analysis connector comprises a discharge resistor.

10. An electric motor vehicle, comprising:
a battery including a controller, and an interface configured to allow measurement of battery properties and/or discharge of the battery when the controller has failed.

11. The battery as claimed in claim 7, wherein the analysis connector is configured to replace the maintenance connector.

12. A method for monitoring a battery including a controller, comprising:
measuring battery properties and/or discharge of the battery with an interface in response to failure of the controller.
